(19) United States
(12) Patent Application Publication
(10) Pub. No.: US 2011/0223706 A1
(43) Pub. Date: Sep. 15, 2011

(54) METHOD OF FORMING A PHOTODETECTOR

(76) Inventors: JILL C. HILDRETH, Austin, TX (US); Stanley M. Filipiak, Pflugerville, TX (US); Marc A. Rossow, Austin, TX (US); Gregory S. Spencer, Pflugerville, TX (US); Bret T. Wilkerson, Pflugerville, TX (US)

(21) Appl. No.: 12/721,278

(22) Filed: Mar. 10, 2010

(51) Int. Cl. H01L 31/18

(52) U.S. Cl. 438/69; 438/93; 257/E31.127; 257/E31.052

(57) ABSTRACT

A photodetector is formed to have a germanium detector on a waveguide. The germanium detector has a first surface on the waveguide and a second surface that, when exposed to ambient conditions, forms germanium oxide. In a processing platform, an oxygen-free plasma is applied to the second surface. The oxygen-free plasma removes oxygen that is bonded to germanium at the second surface. A cap layer is formed on the second surface prior to removing the germanium detector from the processing platform.

### BACKGROUND

1. Field

This disclosure relates generally to forming semiconductor devices, and more specifically, to forming a photodetector.

2. Related Art

Some devices, such as photodetectors, are formed by epitaxially growing germanium over a silicon layer. The prior art has focused on making the interface between the germanium and silicon clean. If the interface is not clean then epitaxial growth is impeded and device performance is degraded.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates a cross-section of a portion of a photodetector having a germanium detector in accordance with an embodiment;

FIG. 2 illustrates the photodetector of FIG. 1 after a germanium oxide is formed over the top surface of a germanium detector in accordance with an embodiment;

FIG. 3 illustrates the photodetector of FIG. 2 after removing the germanium oxide in accordance with an embodiment;

FIG. 4 illustrates the photodetector of FIG. 3 after forming a cap layer over the top surface of the germanium detector in accordance with an embodiment;

FIG. 5 illustrates the photodetector of FIG. 4 after forming contacts in accordance with an embodiment; and

FIG. 6 illustrates a schematic of a platform that may be used to perform the processing of the photodetector illustrated in FIGS. 1-5.

### DETAILED DESCRIPTION

While making the interface between the germanium and silicon clean improves the photodetector performance, the inventors have discovered that a clean top surface of the germanium also affects device performance. The inventors found that germanium oxide is formed if the germanium is exposed to an oxygen environment, which occurs when the photodetector is removed from the tool used to form the germanium detector. This germanium oxide, if present, creates leakage degrading the performance of the device, such as by decreasing the signal to noise ratio. As a result, the inventors have created a treatment process to remove the germanium oxide to improve performance. This treatment process uses an oxygen-free plasma so that radicals (e.g., hydrogen radicals) bond with the oxygen from the germanium oxide and remove the germanium oxide. The result is a pure germanium layer.

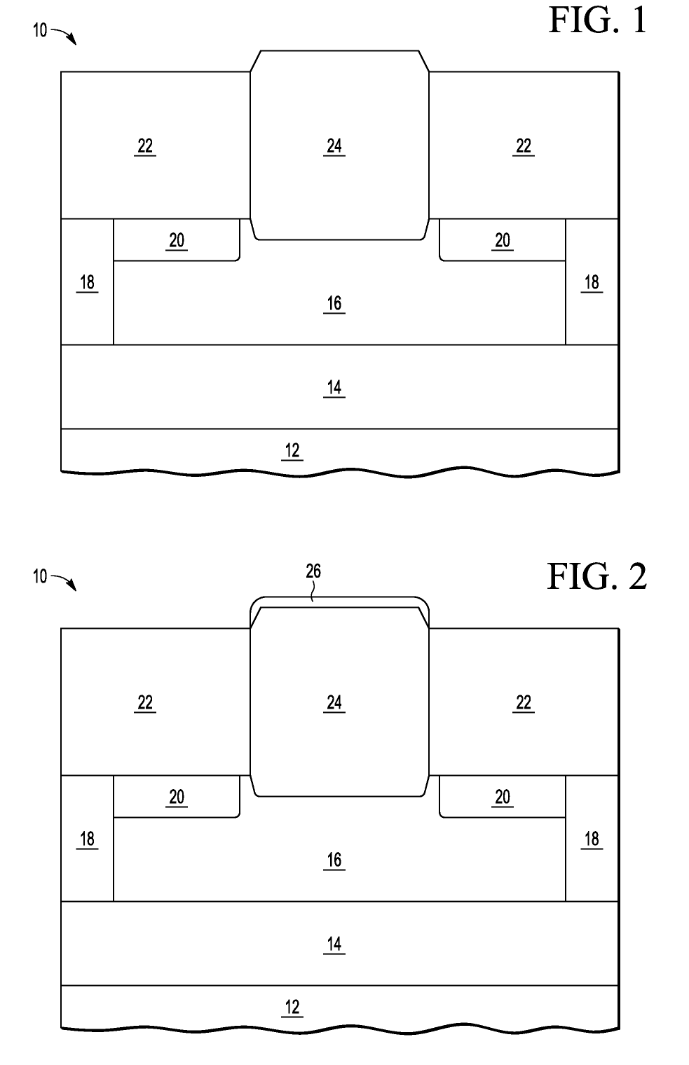

FIG. 1 illustrates a cross-section of a portion of a photodetector 10 having a germanium detector 24 in accordance with an embodiment. In one embodiment, the photodetector 10 includes a silicon-on-insulator (SOI) substrate that includes a first silicon layer 12, a buried oxide (BOX) layer 14, and a second silicon layer 16. In other embodiments, the semiconductor substrate include semiconductor material or combinations of materials, such as gallium arsenide, silicon germanium, silicon-on-insulator (SOI), silicon, monocrystalline silicon, the like, and combinations of the above. In one embodiment, the first silicon layer 12 is a silicon substrate, the BOX layer 14 is 800 nm of silicon dioxide, and the second silicon layer 16 is approximately 310 nm of silicon. Within the second layer 16 are isolation regions 18, which may be shallow trench isolation (STI) regions. The isolation regions 18 may be formed of silicon dioxide. In the embodiment illustrated, the isolation regions 18 extend through the entire second silicon layer 16 and hence are approximately 310 nm in height. Between the isolation regions 18, the second silicon layer is a waveguide region 16. Optical trenches 20 are formed within the waveguide region 16. The optical trenches 20 may be formed of silicon dioxide. In the embodiment illustrated, the optical trenches 20 are more shallow than the isolation regions 18 and are approximately 160 nm in height. In one embodiment, the isolation regions 18 and optical trenches 20 may be the same material and filled and planarized during the same processing steps.

A dielectric 22 is formed over the waveguide region 16, the optical trenches 20, and isolation regions 18. The dielectric 22 may or may not be planarized, patterned, or both. In one embodiment, the dielectric 22 protects the waveguide region 16. The dielectric 22 may have additional functions depending on what layers it includes because the dielectric 22 may include many different layers. For example, the dielectric 22 may include the dielectric layers that were used to form features of other devices (not shown) formed over the semiconductor substrate 12 (e.g., spacers and liner dielectrics). The presence or absence of dielectric layers depends on the particular processing integration being used. The dielectric 22 may be formed by any suitable process, such as a chemical vapor deposition (CVD), atomic layer deposition (ALD), physical vapor deposition (PVD), the like, and combinations of the above. In one embodiment, the dielectric 22 is a silicon protective layer and includes a top layer that is silicon dioxide and a bottom layer of a different material. In one embodiment, the bottom layer includes silicon and nitrogen; for example, the bottom layer may be silicon nitride. In another embodiment, the dielectric 22 only includes one material, such as silicon dioxide. It is desirable that the top layer or the entire dielectric 22 is silicon dioxide, because silicon dioxide has good selectivity for the subsequent germanium formation process. In one embodiment, the dielectric 22 is greater than approximately 50 nanometers (nm) thick. The first dielectric 22 is patterned, using conventional patterning technique to form a window and expose the waveguide region 16. As shown in the illustrated embodiment, the window may also extend into the waveguide region 16.

After forming the window, a clean process may be performed to improve the interface (a first surface) between the germanium detector 24 and the waveguide region 16 to improve performance. For example, the clean process may include an HF (hydrofluoric acid) etch process following by a low temperature oxide growth with O₃, followed by a dry process using N₂, a subsequent HF clean, and another dry process using N₂. Afterwards, the germanium may be grown in the window. In one embodiment, the epitaxial growth is formed by epitaxial growth at a temperature less than 400 degrees Celsius, which in one embodiment is approximately 390 degrees Celsius. Because the growth process is a selective epitaxial process, the top of the germanium detector 24 may be slanted inward at the corners. In prior art methods, epitaxial growth includes two steps: i) a high temperature bake at temperatures greater than 750 degrees Celsius; and ii) growth. However, the high temperature bake may be removed. In one embodiment, instead of a high temperature bake, germane is flowed at a temperature less than 600 degrees Celsius and then HCl (hydrochloric acid) is used to etch the germanium away and further clean the surface. The HCl etch is also performed at less than 600 degrees Celsius. Afterwards, the germanium photodetector 24 is grown. A skilled artisan appreciates that while 600 degrees Celsius may currently be the maximum for the germane flow process if transistors are formed over other portions of the semiconductor substrate 12 that as processes change it is likely that this maximum temperature will decrease, such as to 500 degrees Celsius or even 400 degrees Celsius.

FIG. 2 illustrates the photodetector of FIG. 1 after a germanium oxide 26 is formed over a second or top surface of the germanium detector 24. The germanium oxide 26 is an oxide formed after growing the germanium detector 24 when the germanium detector 24 is exposed to an oxygen-including environment. The germanium detector 24, in one embodiment, may be exposed to oxygen when the detector 10 is removed from the tool used to form the germanium detector 24. In one embodiment, the germanium oxide 26 is approximately 0.5 nm to approximately 2 nm thick.

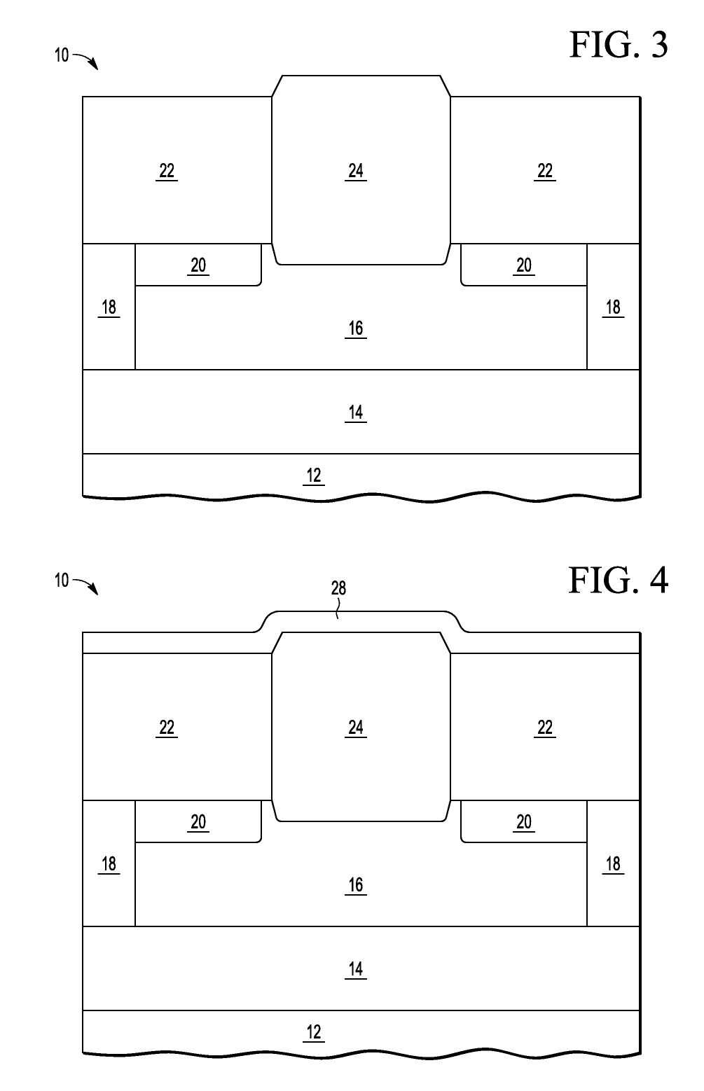

FIG. 3 illustrates the photodetector 10 after the germanium oxide 26 is removed. In one embodiment, an oxygen-free plasma including NH₄ (ammonium), NH₃ (ammonia), SiH₄ (silane), H₂ (hydrogen), the like or combinations of the above is used. In one embodiment, an in-situ plasma is used. Additional chemicals, such as helium and nitrogen may also be used. It is desirable that the chemistry used includes hydrogen so that the hydrogen radicals from the chemistry bonds with the oxygen in the germanium oxide 26. By reacting hydrogen with oxygen, the germanium oxide 26 is removed and the surface of the germanium detector 24 is pure germanium. (A skilled artisan recognizes that in practice a few oxygen atoms may still be present due to manufacturing complexity; however, these oxygen atoms will be undetectable or if detectable will not significantly affect device performance.) In other words, the chemistry removes oxygen that is bonded to germanium at the top surface of the germanium detector 24. The chemistry is oxygen free so that additional oxygen is not added to the germanium oxide 26 defeating the purpose of removing the germanium oxide 26. In one embodiment, 100% NH₃ is used. In another embodiment, approximately 9% NH₃ is used and approximately 91% N₂ is used.

In one embodiment, the radio frequency (RF) power used is approximately 200 Watts. In another embodiment, the RF power is between approximately 100 Watts and less than or equal to approximately 350 Watts. If a lower RF power is used (e.g., 100 Watts) the processing time may need to be extended to significantly remove the germanium oxide 26 as compared to using a higher RF power (e.g., 200 Watts). In one embodiment, if 200 Watts is used, the time may be approximately 40 seconds. The RF power may be chosen so that it is great enough to promote the creation of free hydrogen to bond with the oxygen in the germanium oxide 26, but low enough to minimize or prevent other elements, if present, such as nitrogen, to undesirably roughen the surface of the germanium detector 24.

In one embodiment, a pressure of approximately 3 Torr to approximately 30 Torr may be used. For example, approximately 8 Torr or approximately 4.2 Torr may be used. In one embodiment, the oxygen-free plasma process may be approximately 20 seconds to approximately 100 seconds, such as approximately 40 seconds. In one embodiment, a temperature of approximately 350 degrees Celsius to approximately 425 degrees Celsius, such as approximately 400 degrees Celsius, may be used. In one embodiment, the flow range may be approximately 200 sccms to approximately 8000 sccms. In one embodiment, the flow rage may be approximately 400 sccms of NH₃ or approximately 6000 sccms of 91% N₂ and 500 sccms of 9% of NH₃.

FIG. 4 illustrates the photodetector 10 after removing the germanium oxide 26 and forming a cap layer 28. In one embodiment, the cap layer 28 is approximately 20 nm to approximately 200 nm of oxynitride (SiON), such as approximately 120 nm. The cap layer 28 may be formed by any suitable process, such as CVD, PVD, ALD, the like, or combinations of the above. For example, the cap layer 28 may be formed by plasma enhanced chemical vapor deposition (PECVD) using SiH₄, N₂ (nitrogen), N₂O (nitrous oxide), TEOS (tetra ethyl orthosilicate), O₂ (oxygen), and He (helium). In one embodiment, the cap layer 28 may include carbon. For example, the cap layer 28 may include SiCN (silicon carbon nitride), SiN (silicon nitride), SiCON (silicon carbon oxynitride), or SiO₂ (silicon dioxide). It is desirable that the cap layer protects the germanium detector 24 during subsequent wet etches used in the manufacturing process. The cap layer will also prevent or minimize germanium oxide growth at the top surface (the surface near the cap layer 28) of the germanium detector 24. In one embodiment, the cap layer is formed at the substantially the same temperature, meaning that the temperatures are the same when rounded to the nearest tenth (e.g., 630 and 643 degrees Celsius), as the removal of the germanium oxide process.

In one embodiment, the process of removing the germanium oxide 26 is performed in the same chamber (i.e., in-situ) as the process for forming the cap layer 28. In another embodiment, these two processes are formed in separate chambers, but in the same platform. In any of these embodiments, the photodetector 10 is not exposed to oxygen after the germanium oxide 26 is removed and prior to forming the cap layer 28 to avoid germanium oxide from being formed over the germanium detector 24. More specifically, the exemplary platform 40 illustrated in FIG. 6 may be used. The platform 40 may include four chambers 41-44 which are physically connected together through a mainframe 50. The chambers 41-44 and the mainframe 50 are under vacuum. The platform 40 also includes load locks 48, which are the chambers where the wafers are loaded into the platform 40 from the outside environment that is not under vacuum. An arm 46 exists in the mainframe 50 to move wafers among the chambers 41-44 and the load locks 48. In the embodiment illustrated, the photodetector 10 is in chamber 42. For example, both the process for removing the germanium oxide 26 and the forming of the cap layer 28 may occur in the chamber 42. In another embodiment, one of these processes may be formed in a different chamber, such as chambers 41, 43, and 44.

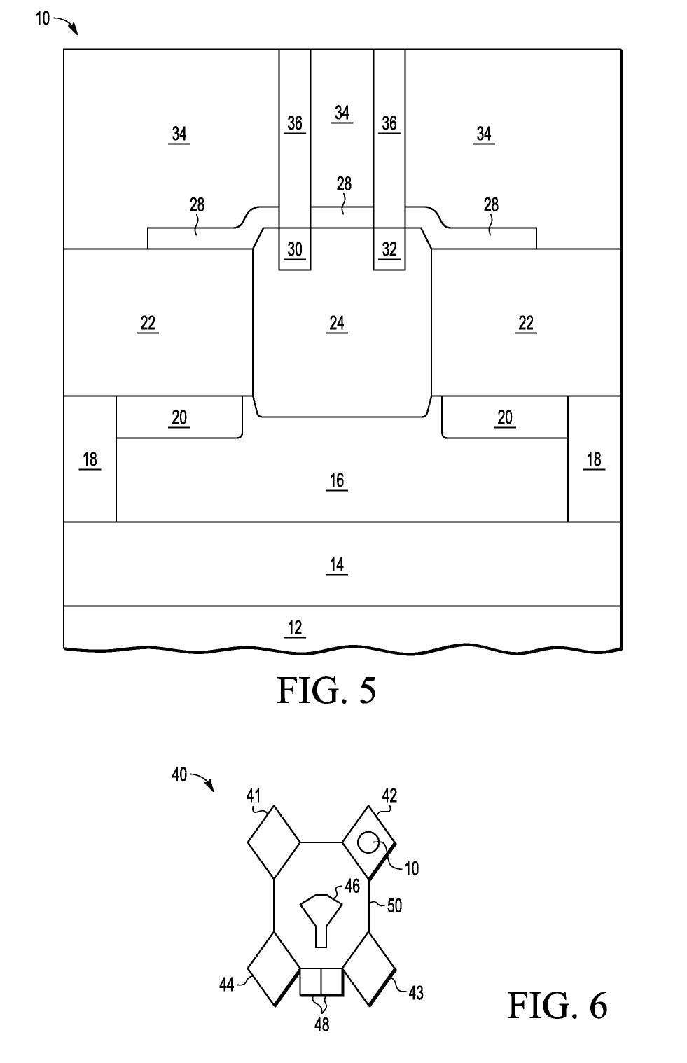

FIG. 5 illustrates further processing of the photodetector 10 after forming the cap layer 28. The cap layer 28 may be etched to remove portions of the cap layer from the dielectric 22 and other portions of the device (not illustrated). Next, implant(s) and anneal(s) may be performed to form an N-type implant region 30 and a P-type implant region 32 within the germanium detector 24. (A skilled artisan recognizes that the N-type implant region 30 and the P-type implant region 32 may be interchanged.) For example, the N-type implant region 30 may be doped N+ and the P-type region 32 may be doped P+. Therefore, two mask and implant process may be used. However, one anneal can be performed after the implant of both the N-type and P-type species, or an anneal can be used following the individual implantation of the N-type and P-type species. In one embodiment, the N-type species is annealed at a temperature between approximately 500 degrees Celsius to approximately 600 degrees Celsius, or more specifically approximately 550 degrees Celsius to approximately 600 degrees Celsius, and the P-type species is annealed at a temperature between approximately 400 degrees Celsius to approximately 600 degrees Celsius. There is more latitude in the annealing temperature for the P-type species than for the N-type species since the P-type species is relatively easy to activate and does not diffuse as much as the N-type species. If only one anneal is being performed to anneal both the N-type and P-type species than a temperature between approximately 500 degrees Celsius to approximately 600 degrees Celsius can be used.

After forming the regions 30 and 32, a dielectric 34 is formed over the cap layer 28 and the dielectric 22. Any suitable process or materials, such as those described for the dielectric 22 may be used to form the dielectric 34. In one embodiment, the dielectric 34 is approximately 500 nm of silicon dioxide. Next, contacts 36 are formed within the dielectric 34 by forming vias in the dielectric 34 and filling the vias with a conductive material. Additionally, planarization may be performed. In one embodiment, the contacts 36 include tungsten. The contacts 36 electrically connect the germanium detector 24 to outside the photodetector 10, for example, through interconnect structures (not shown), which are formed using subsequent processing known to a skilled artisan.

By now it should be appreciated that there has been provided a method for reducing surface contamination on a germanium film to reduce leakage current of the photodetector. The chemistry chosen to remove the germanium oxide is chosen so that a chemical bonds with the oxygen and removes the resulting species so that only germanium remains. If the germanium oxide 26 was not removed then it would exist at the top surface of the germanium detector 24. The portion of the germanium oxide 26 between the regions 30 and 32 would provide a leakage path between these regions together because the germanium oxide 26 is a better conductor than germanium. The process to remove the germanium oxide can be used in a manufacturing environment. The inventors have found that by using the above process the time between exposure to atmosphere after forming the germanium detector 24 to the start of the plasma treatment can be approximately 72 hours or less, such as 48 hours, without degrading the performance of the photodetector 10.

Unless stated otherwise, terms such as “first” and “second” are used to arbitrarily distinguish between the elements such terms describe. Thus, these terms are not necessarily intended to indicate temporal or other prioritization of such elements. The term “coupled,” as used herein, is not intended to be limited to a direct coupling or a mechanical coupling. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

What is claimed is:

1. A method of forming a photodetector, comprising:
forming a waveguide region;
forming a germanium detector having a first surface and a second surface, wherein the first surface is on the waveguide region;
in a processing platform, applying an oxygen-free plasma to the second surface which removes oxygen that is bonded to germanium at the second surface; and
forming a cap layer on the second surface prior to removing the germanium detector from the processing platform.

2. The method of claim 1, wherein the oxygen-free plasma comprises one of a group consisting of hydrogen and ammonia.

3. The method of claim 2, wherein the step of applying the oxygen-free plasma is further characterized as being applied at a high frequency power, wherein the high frequency power is applied within a range of 100 watts to 350 watts.

4. The method of claim 3, wherein the oxygen-free plasma further comprises one of a group consisting of helium and nitrogen.

5. The method of claim 4, wherein the step of applying an oxygen-free plasma and the step of forming the cap layer are performed at substantially the same temperature.

6. The method of claim 5, wherein forming the cap layer comprises forming an oxynitride layer.

7. The method of claim 6, further comprising:
forming a first region of a first conductivity type in the germanium detector;
forming a second region of a second conductivity type in the germanium detector;
forming contacts to the first and second regions; and
forming a dielectric layer over the cap layer.

8. The method of claim 7, wherein the forming the contacts comprises:
forming a first opening through the dielectric layer and the cap layer to the first region and a second opening through the dielectric layer and the cap layer to the second region; and
filling the first opening and the second opening with a conductive material.

9. The method of claim 1, further comprising forming a germanium oxide layer on the second surface by exposing the second surface to ambient conditions prior to the step of applying the oxygen-free plasma.

10. The method of claim 1, wherein the steps of forming the cap layer and applying oxygen-free plasma are further characterized as being performed in a first chamber of the processing platform.

11. The method of claim 1, wherein the step of applying the oxygen-free plasma is further characterized as being performed in a first chamber of the processing platform and the step of forming the cap layer is further characterized as being performed in a second chamber of the processing platform.

12. A method of forming a photodetector, comprising:
forming a waveguide region surrounded by an isolation region;
forming a germanium detector having a bottom surface on the waveguide region;
applying an oxygen-free plasma comprising ammonia to a top surface of the germanium detector, wherein the oxygen-free plasma is applied with a radio frequency having a power in a range of 100 to 350 watts; and
after applying the oxygen-free plasma, forming a cap layer on the top surface of the germanium detector.

13. The method of claim 12, wherein the step of applying the oxygen-free plasma is further characterized as separating hydrogen from the ammonia and reacting the hydrogen with oxygen that is bonded to the germanium detector at the top surface of the germanium detector.

14. The method of claim 12, further comprising:
placing the germanium detector in a processing platform prior to the step of applying the oxygen-free plasma;
wherein:
the step of applying the oxygen-free plasma is performed in the processing platform under vacuum; and
the step of forming the cap layer is performed in the processing platform without breaking vacuum.

15. The method of claim 12, wherein the steps of applying the oxygen-free plasma and forming the cap layer are performed at substantially the same temperature.

16. The method of claim 12, wherein the step of forming the cap layer is further characterized by the cap layer functioning to prevent wet cleans from the contacting the germanium detector.

17. The method of claim 16, wherein the step of forming the cap layer is further characterized as depositing oxynitride to form the cap layer.

18. A method of forming a photodetector, comprising:
forming a waveguide region comprising silicon surrounded by an isolation region;
forming a germanium detector on the waveguide region;
forming a germanium oxide layer on a top surface of the germanium detector by exposing the top surface of the germanium detector to ambient conditions;
placing the germanium detector in a processing platform;
applying an oxygen-free plasma to the germanium oxide layer to remove the germanium oxide layer while in the processing platform under vacuum; and
forming a cap layer on the top surface of the germanium detector while still in the processing platform and without breaking vacuum after the step of applying the oxygen-free plasma.

19. The method of claim 18, wherein the step of applying the oxygen-free plasma comprises applying ammonia at a radio frequency that has a power in the range of 100 to 350 watts.

20. The method of claim 19, wherein the step of forming the cap layer is further characterized by the cap layer functioning to prevent wet cleans from contacting the germanium detector.
